(19) United States
(12) Patent Application Publication
(10) Pub. No.: US 2025/0163565 A1
(43) Pub. Date: May 22, 2025

(54) SOURCE ARRANGEMENT AND TLE SYSTEM

(71) Applicant: MAX-PLANCK-GESELLSCHAFT ZUR FÖRDERUNG DER WISSENSCHAFTEN E.V., München (DE)

(72) Inventors: Wolfgang BRAUN, Bietigheim-Bissingen (DE); Jochen MANNHART, Böblingen (DE)

(21) Appl. No.: 18/839,257

(22) PCT Filed: Mar. 14, 2022
(86) PCT No.: PCT/EP2022/056542

§ 371 Date: Aug. 16, 2024

(51) Int. Cl. C23C 14/28

(52) U.S. Cl. CPC C23C 14/28

(57) ABSTRACT

The invention relates to a source arrangement (10) for a TLE system (100) for providing a source element (12) comprising or consisting of a source material (14) to be evaporated and/or sublimated by a laser beam (112), comprising a support (20) carrying said source element. Further, the invention relates to a TLE system (100) comprising a laser source (110) for providing a laser beam (112), a reaction chamber (120) for containing a reaction atmosphere (124), a source arrangement (10) for providing a source element (12) comprising or consisting of a source material (14) to be evaporated and/or sublimated by the laser beam (112) within the reaction chamber (120), and a substrate arrangement (130) for providing a substrate (132) to be coated within the reaction chamber (120) with the evaporated and/or sublimated source material (14). In addition, the invention relates to a method for using a TLE system (100), the TLE system (100) comprising a laser source (110) for providing a laser beam (112), a reaction chamber (120) for containing a reaction atmosphere (124), a source arrangement (10) for providing a source element (12) comprising or consisting of a source material (14) to be evaporated and/or sublimated by the laser beam (112) within the reaction chamber (120), and a substrate arrangement (130) for providing a substrate (132) to be coated within the reaction chamber (120) with the evaporated and/or sublimated source material (14).

The invention relates to a source arrangement for a TLE system for providing a source element comprising or consisting of a source material to be evaporated and/or sublimated by a laser beam, comprising a support carrying said source element. Further, the invention relates to a TLE system comprising a laser source for providing a laser beam, a reaction chamber for containing a reaction atmosphere, a source arrangement for providing a source element comprising or consisting of a source material to be evaporated and/or sublimated by the laser beam within the reaction chamber, and a substrate arrangement for providing a substrate to be coated within the reaction chamber with the evaporated and/or sublimated source material.

In thermal laser evaporation (TLE), material is evaporated and/or sublimated in a controlled environment, in particular in a reaction chamber filled with a reaction atmosphere, by means of laser heating, usually with the intent to coat a surface with a thin film. However, also undesired or even harmful coating of elements present within the reaction camber, such as for instance the inner surface of entrance windows or laser mirrors, can occur.

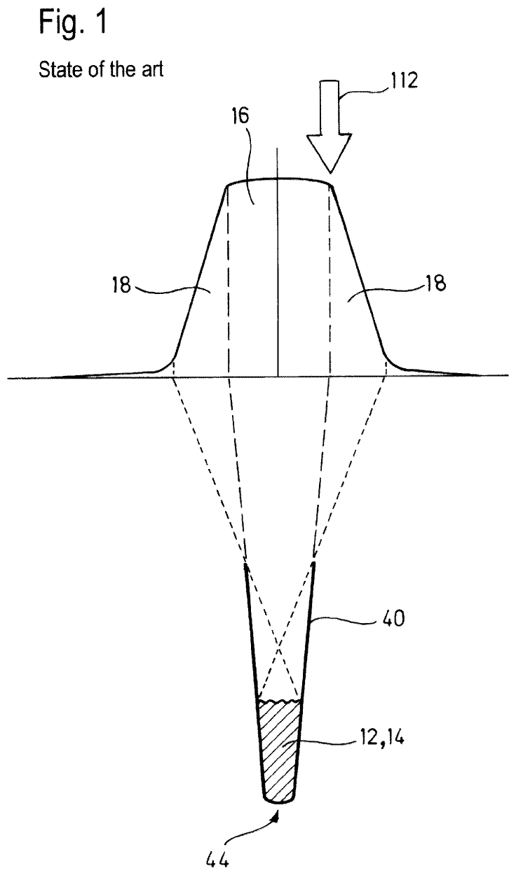

As depicted in FIG. 1, a usage of elongated crucibles 40 for providing the source material 14 to be evaporated and/or sublimated provides the advantage of a confined region of high deposition rates with very weak radial dependence. In the lower part of FIG. 1, a source element 12 arranged at a bottom end 44 of such a crucible 40 is depicted. Said source material 14 is evaporated and/or sublimated by a laser beam 112.

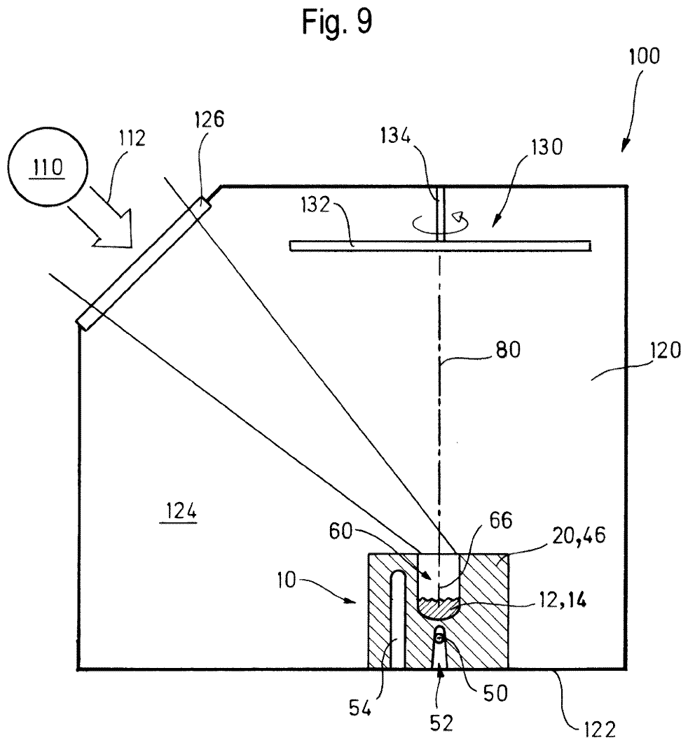

The top part of FIG. 1 depicts a distribution of evaporated and/or sublimated source material 14 at a position of a substrate 132 (not shown, see FIG. 9) at the horizontal axis of the distribution diagram. Any point of the substrate 132 within the central part 16 of the distribution is irradiated by molecules in direct line of sight from the entire exposed surface of the source element 12. Hence, in this region, the deposition rate is the highest, with very weak radial dependence.

In the wing parts 18 of the distribution adjacent to the center part 16, the flux of source material 14 is partly shadowed by the walls of the crucible 40. Within this region, an approximately linear and strong decrease of the deposition is observed when moving radially outward. In the parts of the distribution further outwards, only source material 14 re-emitted from the walls of the crucible 40 walls reaches the plane in which the substrate 132 is arranged. The deposition rate in these parts is small, typically less than 10% of the peak value, and continues to fall off rapidly with increasing distance from the center.

However, FIG. 1 also makes obvious the problem of said usage of elongated crucibles 40. For reaching the surface of the source element 12, the laser beam 112 has to be aligned very steep with respect to the crucible 40. This locates the laser beam 112 in the central part 16 or at least at the boundary between central part 16 and wing part 18 of the distribution of the evaporated and/or sublimated source material 14. First of all, said positioning of the laser beam 112 limits the available space for the substrate 132 to be coated. In addition, it brings the risk of unwanted or even harmful coating of guidance elements of the laser beam 112 such as mirrors or entrance windows 126 (see FIG. 9), leading to higher maintenance costs and shorter maintenance intervals.

In TLE systems according to the state of the art, the latter problem is addressed by arranging an aperture in the path of the laser beam between the entrance window and the source element. However, the aperture and the laser beam require some effort to be and to stay aligned, such as adjustment elements and a camera to view and control the position of the beam at the aperture. In addition, materials that need to be evaporated and/or sublimated at high fluxes require large sources that need to be moved upwards during deposition by larger distances than the other sources. This requires additional positioning elements within the chamber.

In view of the above, it is an object of the present invention to provide an improved source arrangement, an improved TLE system and an improved method of using a TLE system which do not have the aforementioned drawbacks of the state of the art. In particular, it is an object of the present invention to provide an improved source arrangement, TLE system and method of using a TLE system, which allow stable, high-flux evaporation with very weak radial dependence with simultaneously prohibiting unintentional coating of elements of the TLE system.

This object is satisfied by the respective independent patent claims. In particular, this object is satisfied by a source arrangement according to independent claim 1, by a TLE system according to independent claim 26, and by a method of using a TLE-system according to independent claim 34. The dependent claims describe preferred embodiments of the invention. Details and advantages described with respect to a source arrangement according to the first aspect of the invention also refer to a TLE system according to the second aspect of the invention and to a method according to the third aspect of the present invention, and vice versa, if of technical sense.

According to the first aspect of the invention, the object is satisfied by a source arrangement for a TLE system for providing a source element comprising or consisting of a source material to be evaporated and/or sublimated by a laser beam, comprising a support carrying said source element, wherein the support encloses a free space free of any structural elements of the support, whereby the free space is elongated along a central axis of the free space and thereby has a columnar shape, wherein an opening disposed in a surface portion of the support provides access from outside of the support to the free space, the opening defining an upper end of the free space, and the source element disposed within the support spaced from the opening along the central axis of the free space defining a lower end of the free space, and wherein a wall structure of the support surrounding the free space between the upper end and the lower end comprises a mirror surface reflective to the laser beam.

The source arrangement according to the first aspect of the present invention is intended for usage with or within a thermal laser evaporation system (TLE system). For this purpose, the source arrangement can be arranged within a reaction chamber of the TLE system filled with a reaction atmosphere. Suitable means for the placement and fixation of the source arrangement can be part of the source arrangement and/or the reaction chamber.

The source arrangement is used for providing the actual source element to be evaporated and/or sublimated. The source element itself can comprise one or more source materials, in particular can consist of a single source material for high purity requirements. The source arrangement comprises a support for carrying a single source element. However, also embodiments of a source arrangement comprising two or more supports, each of them carrying a single source element are possible. In this case, the different source elements can be identical or comprise different compositions of source materials.

In particular, the support encloses a free space. Said free space is free of any other structural element of the support. Hence, said free space is also free of structural elements of the remaining source arrangement and of the other parts of the TLE system. However, the free space is accessible from outside of the support through an opening in the surface of the support. Hence, when used within a TLE system, the free space is open to the inside of the reaction chamber and hence will be filled with the reaction atmosphere.

The shape of the free space is elongated along a central axis of the free space. In other words, the extension of the free space along its central axis is larger that its extension perpendicular to said central axis. The central axis itself is a virtual straight line, preferably passing through a center of respective cross sections of the free space perpendicular to the central axis. The described different extensions of the free space along and perpendicular, respectively, to its central axis provide the free space with a columnar shape.

As already mentioned, the free space is accessible from outside of the support through an opening in a surface of the support. In fact, said opening defines an upper end of the free space. In other words, the free space starts at the opening in the surface of the support and extends inwards into the support. Adjacent of the upper end the free space comprises its columnar middle part as described above. A wall structure of the support surrounds said middle part of the free space. A lower end of the free space is defined by the source element. The free space ends at a surface of the source element facing the free space. For that the source element is accordingly arranged within the support. The support itself comprises suitable means for arranging the source element within the support at the desired and designed position.

In summary, the support of the source arrangement according to the present invention provides and carries the source element. The source element is arranged within the support and is accessible via the opening in the surface of the support. Between the opening and the support, a columnar free space is extending. In other words, the placement of the source element within the support defining the lower end of the free space forms a device similar to an elongated crucible. By evaporating and/or sublimating the source material of the source element, a confined region of high deposition rates with very weak radial dependence can be provided. Essentially, this region of high deposition rates is anchored to a virtual extension of the central axis beyond the upper end of the free space.

Essentially for the source arrangement according to the first aspect of the present invention, the wall section of the support comprises a mirror surface reflective to the laser beam. In particular, the mirror surface may specularly and/or diffusely reflect the laser beam. As already mentioned, said wall structure surrounds the middle part of the free space between the upper end and lower end, respectively, of the free space. By providing the mirror surface, the laser beam for the evaporation and/or sublimation of the source material no longer has to be directly impinging onto the source element, but can once or several times be reflected on the mirror surface. The laser beam enters the free space and is guided by the one or more reflections on the mirror surface within the free space towards the source element.

Hence, the initial direction of the laser beam, in other words the direction of the laser beam when it enters the free space, can be chosen without the limitation of a presence of a direct line-of-sight to the source element. Therefore, the laser source providing the laser beam, or at least the last optical element in the path of the laser beam before the entrance of the laser beam into the free space, can be arranged and positioned within the reaction chamber such that it is located outside of the above-mentioned central part of the distribution of the evaporated and/or sublimated source material, preferably even outside of the wing parts of the distribution adjacent to said central part. An unintentional and often harmful coating of elements of the laser system can thereby be avoided or at least be reduced.

In summary, the source arrangement according to the first aspect of the present invention provides a high-density region of evaporated and/or sublimated source material with a very low radial dependence, eminently suitable for placing the substrate thereon. This is due to the elongated, columnar shape of the free space, which narrows and trims the flux of evaporated and/or sublimated source material. Further, with the reflecting mirror surface a placement of the laser source, or at least of the last element of the laser guidance system within the reaction chamber, in regions with low or even negligible flux of evaporated and/or sublimated source material is possible. Unwanted or even harmful coating of said guidance elements of the laser beam such as mirrors or entrance windows, leading to higher maintenance costs and shorter maintenance intervals, can thereby be avoided.

Further, the source arrangement according to the present invention can comprise that the mirror surface completely encompasses the free space along the central axis. In other words, independent from the angle around the central axis, the laser beam will be reflected by the mirror surface of the wall structure. Alignment of the source arrangement within the reaction chamber can thereby be simplified. In addition, also multiple reflections of the laser beam on the mirror surface can be provided more easily, as no dedicated second reflective area for the second, fourth, and so on reflection within the free space has to be provided.

In addition, the source arrangement according to the present invention can be characterized in that the mirror surface at least partly comprises a wavy surface structure for diffusing the reflected laser beam. As the free space is surrounded by the mirror surface of the wall structure, focusing effects of the laser beam might occur, thereby leading to very high-power densities near the respective focal point. Such a focal point may lead to unstable evaporation and/or sublimation, source contamination by excessive heating of the support, or even a failure of the support. To avoid this, it is beneficial for the mirror surface to have a wavy surface morphology, in particular a wavy surface with a well-defined range of local surface inclinations, which diffuses the reflected laser beam into a well-defined angular range when reflecting it. This angular range should be as large as possible to ensure good averaging and spreading of the radiation, however at the same time remain small enough such that the longitudinal propagation of the incoming beam is not reversed to a substantial degree before reaching the source material. In particular, grinding, e.g. with sand paper, preferably with a grain size of about 800, along the direction of the main axis of the free space is beneficial for a sideways diffusion with respect to the propagation direction into the free space, while at the same time minimizing reflections that reverse the direction of beam propagation towards the upper end of the free space.

In another embodiment of the source arrangement according to the present invention, the cross section of the opening completely contains the cross section of the upper end of the free space. The opening in the surface of the support defines the upper end of the free space. By completely containing the cross section of the upper end by the opening, the complete cross section of the upper end of the free space is accessible for the both incoming the laser beam and the outgoing evaporated and/or sublimated source material, respectively. Thereby an absorption of the laser beam before entering the free space and also a deposition of evaporated and/or sublimated source material at the upper end of the free space can be avoided.

The source arrangement according to the present invention can be enhanced further by that the cross section of the opening is identical to the cross section of the upper end of the free space. Thereby, an extension of the opening in the support beyond the size needed for the cross section of the upper end of the free space is avoided. An especially compact setup of the support can thereby be provided. As the opening in the surface of the support also allows access to the inside of the support, additionally said inside of the support can be protected against unwanted and possibly harmful entry into the support, for instance of the reaction gas or of the evaporated and/or sublimated source material.

Further, the source arrangement according to the present invention can be characterized in that an extent of the free space along the central axis is equal to or larger, in particular two times larger or more, than a diameter of its upper end. As already described above, in the wing parts adjacent to the central of the distribution of the evaporated and/or sublimated source material the flux of source material is partly shadowed. Hence, the size of said wing parts is directly correlated to the extension of the free space along its central axis, as this shadowing effect increases with the extension. By providing the free space with an extent along the central axis equal to or larger, in particular two times larger or more, than a diameter of its upper end, especially small wing parts of the distribution of the evaporated and/or sublimated source material and hence an especially defined central part of the central part of the distribution can be provided.

According to an embodiment of the source arrangement according to the present invention, the free space is rotationally symmetric to the central axis. Hence, also the provided central part of the distribution of evaporated and/or sublimated source material is rotationally symmetric to the central axis and its virtual extension beyond the upper end of the free space. A regular and uniform coating of an accordingly arranged substrate can thereby be provided more easily. In addition, in particular in combination with a mirror surface surrounding the free space, also the internal reflections of the laser beam on the mirror surface can be provided independent from the angle around the central axis at which the laser beam enters the free space through its upper end.

In a first alternative embodiment, the source arrangement according to the present invention can be enhance by that the free space is cylindrical. In other words, the wall structure of the support and in particular the mirror surface is aligned parallel or at least essentially parallel to the central axis. Thereby, the average reflection angle inside the cylindrical free space remains constant with respect to the central axis of the free space, in particular independent of the number of reflections. Additionally, also the cross section of the source element defining the bottom end stays constant. Hence, the central part of the distribution of evaporated and/or sublimated source material stays constant or at least essentially constant independent of the actual positioning of said surface of the source element and the extent of the free space along its central axis, respectively.

In a second alternative embodiment, the source arrangement according to the present invention can be enhance by that the free space is conical. In other words, the wall structure of the support and in particular the mirror surface is aligned angled to the central axis by an opening angle. In this case, an average reflection angle with respect to the central axis is reduced by the opening angle with every reflection. The geometry therefore has to be designed such that the laser beam reaches the source element defining the lower end of the free space before it reverses its propagation direction along the central axis. On the other hand, this optimization also allows a rather small longitudinal propagation of the laser beam with a well homogenized and longitudinally concentrated power density close to the lower end of the free space and hence to the source material to be evaporated and/or sublimated. In addition, due to the more and more homogeneous mixture of the reflected laser beams after multiple reflections, such a configuration more homogeneously heats the source element in this area, thereby helping to achieve homogeneous and efficient evaporation or sublimation.

Further, the source arrangement can be characterized in that the support comprises a crucible of tubular shape with a closed bottom end, whereby the source element is arranged at the bottom end and the crucible encompasses the free space and is thus partially at least part of the wall structure of the support. Crucibles are well known devices for providing source elements with a wide variety of possible source materials, including liquid source materials or source materials which will melt completely when irradiated with a laser beam of sufficient energy density. By implementing a crucible as part of the support, in particular as the inner surface encompassing the free space, these known features of crucibles can be provided also by a source arrangement according to the present invention. However, the respective crucible has to provide the respective shape and dimensions, in particular for the elongated free space with columnar shape to be encompassed by the crucible.

Alternatively, the source arrangement according to the present invention can comprise that the source element is self-supporting and the support comprises a retainer of tubular shape with an open bottom end, whereby the source element is inserted through the bottom end into the retainer, and the retainer encompasses the free space and is thus at least partially part of the wall structure of the support. The retainer of this embodiment resembles a crucible as described above, with the difference that the retainer comprises an open bottom end. Self-supporting source elements can be inserted through said open bottom end. By that, for instance a replacement of the source element, especially also a replacement by a source element comprising a different composition of source materials, can be provided more easily, in particular without changing the retainer. Preferably, the retainer comprises a constant, especially preferred a circular, cross section, at least in the section, in which the source element is inserted. Also preferred, the source element comprises a cross section adapted to the respective cross section of the retainer, in particular a cross section of the same shape and a slightly smaller size. By that, the complete bottom end of the retainer can be filled by the source element, and hence also the lower end of the free space defined by the source element. In particular, the complete laser beam reaching the lower end of the free space is absorbed by the source element.

In a further enhanced embodiment, the source arrangement according to the present invention can be characterized in that the support comprises an actuator for moving the source element within the retainer, in particular towards the upper end of the free space. In this embodiment, the source element may be moved, in particular along the central axis. In this way, during operation, the surface of the source element, and hence the source material actually evaporated and/or sublimated, is moved upwards. Thereby, during operation said surface of the source element, can be kept at the same position within the retainer. Like this, flux transients due to a depletion of the source element during operation can be avoided. Since the source element can be in principle of any length, the source arrangement can be operated for a long time under constant operating conditions, as the relative geometry of the laser beam, the mirror surface of the wall structure, and the surface of the source element at a constant position do not change in time. Alternatively, or additionally at different times, the position of the said surface of the source element may be kept at different steady-state positions with respect to the upper end of the free space during operation, thereby allowing altering the resulting distribution of the flux of evaporated and/or sublimated source material, in particular with respect to the widths of the wing parts of the flux distribution. In particular, the position of the source element within the retainer may also be changed dynamically during operation, thereby allowing strong variations of the flux distribution and hence of a thickness profile of source material deposited onto the substrate.

Further, the source arrangement can comprise that the support comprises an enclosure surrounding one or more crucibles and/or retainers along the central axis at least in the region of the free space of the respective crucible or retainer and is thus at least partially part of the wall structure of the support. Said enclosure can for example, support structural stability of the crucible or the retainer, respectively. In particular, also an exchange of the crucible or the retainer, including the respective source element, with continued use of the same enclosure is possible. In summary, the usage flexibility of the source arrangement according to the present invention can be increased.

In addition, the source arrangement according to the present invention can be enhanced by that the enclosure completely encloses the one or more crucibles and/or retainers and the respective source elements except for an opening forming the upper end of the free space. In other words, the enclosure comprises an enclosed volume, one for each crucible or retainer, respectively, starting with an opening in the surface of the support and extending into the bulk of the support. Such an enclosed volume can provide preventing leakage of source material, especially liquid source material, and/or of parts of the laser beam missing the mirror surface and the source element. Possible harm to the remaining source arrangement or the TLE system as a whole by such a failure can thereby be avoided.

According to one embodiment of the source arrangement according to the present invention, a surface of the crucible or the retainer facing the free space is the mirror surface of the wall structure of the support. Hence, the inner surface directly facing the free space, both of the crucible and the retainer, respectively, forms the mirror surface. No other elements are necessary for providing the mirror surface, thereby simplifying the design of the source arrangement according to the present invention. As the respective crucible and retainer, respectively, encompasses the free space between its upper end and its lower end, also the mirror surface formed by the crucible and retainer, respectively, encompasses the free space. Thereby reflecting the laser beam can be provided independent of the direction of the laser beam.

According to an enhanced embodiment of the source arrangement according to the present invention, at least the portion of the crucible or the retainer forming the mirror surface, preferably the complete crucible or retainer, is made of aluminum or tantalum or molybdenum or stainless steel. All of these materials provide at least one of the following properties, namely stability, high melting point and/or good reflectivity. For each source element comprising different compositions of source materials, the most suitable material for the crucible or the retainer, respectively, can be provided.

Alternatively to the embodiments described in the previous two paragraphs, the source arrangement can be characterized in that a material of the crucible or the retainer is at least partly transparent for the laser beam and a surface of the enclosure facing the free space is the mirror surface of the wall structure of the support. The laser beam is transmitted through the transparent crucible or retainer, respectively, and reflected by the surface of the enclosure forming the mirror surface. For this variant to work, the enclosure needs to be highly reflective to avoid a dominant absorption of the laser power in the enclosure. As the crucible or retainer, respectively, is transparent for the laser beam, no or at least essentially no absorption of laser energy occurs into the material of the crucible or retainer, respectively. Hence, heating of the source element by only the impinging laser beam can be ensured. Further, as the mirror surface reflecting the laser beam is at least a little distanced to the surface of the source element, also heating of side surfaces of the source element different to the surface of the source element defining the lower end of the free space, at least close to said lower end, can be provided.

The source arrangement according to the present invention can be enhanced further by that the crucible or the retainer is at least partly, preferably completely, made of quartz or sapphire or borosilicate glass. In a large number of applications of TLE systems, the laser beam comprises a wavelength of about 1 μm. The listed materials, quartz, sapphire, and borosilicate glass, respectively, are highly transparent for light with this wavelength. Simultaneously, quartz, sapphire, and borosilicate glass, respectively, are stable enough for being manufactured into crucibles and retainers, and for providing the needed support for the source elements.

In addition, the source arrangement according to the present invention can comprise that the enclosure is least partly, preferably completely, made of Aluminum. Aluminum as material for the enclosure is most useful, as it can be easily machined with high precision. Further it comprises a high thermal conductivity, suitable for instance for indirect temperature measurements of the source element and/or active cooling or heating. Further, for a usage as mirror surface, Aluminum is highly reflective for the commonly used laser beams with a wavelength of about 1 μm. In addition, also machining the surface of the enclosure with the required almost smooth surface finish with the defined angular spread as discussed above for providing a wavy surface structure for diffusing the reflected laser beam can be provided easily with Aluminum as material for the enclosure.

Further, the source arrangement according to the present invention can be characterized in that the crucible or the retainer and the enclosure touch at three contact points. For effectively evaporating and/or sublimating source material, preferably all energy deposited from the laser beam into the source element should be used for this purpose. Touching surfaces between the crucible or retainer, respectively, and the enclosure can lead to an unwanted flow of thermal energy away from the source element. Three contact points are the minimum number of contact points for ensuring a stable placement of the crucible or retainer, respectively, within the enclosure. Hence, by providing only three and in addition point-like contact areas between the crucible or retainer, respectively, and the enclosure, an avoidable drain of thermal energy of the source element can be avoided.

In another embodiment, the source arrangement according to the present invention can be characterized in that the support comprises one or more temperature sensors arranged at and/or within the enclosure for measuring the temperature of the source element. By arranging the temperature sensors at and/or within the enclosure at least an indirect measurement of the temperature of the source element, preferably of the surface of the source element defining the lower end of the free space, can be provided. Such a measurement might be rather indirect, since a temperature gradient through the source element, the thermal impedance mismatch of heat conduction through the material of the crucible or retainer, respectively, and the gap to the enclosure, and heat dissipation in the enclosure will distort the results. On the other hand, although being probably systematically off from the true surface temperature of the source element, such a temperature measurement may still be useful for process control to, e.g., stabilize the temperature at a given value, or to ensure run-to-run stability.

According to an enhanced embodiment of the source arrangement according to the present invention, the one or more temperature sensor is a thermocouple or a pyrometer. Both thermocouples and pyrometers, respectively, are suitable temperature sensors to be used for measuring the temperature of the source element. While thermocouples are arranged in direct contact to a surface to be monitored, pyrometer allow a distanced arrangement of the sensor. Hence, depending on the boundary conditions, the temperature sensor suited best can be chosen.

In addition, the source arrangement according to the present invention can be enhanced further by that the enclosure comprises one or more bores, wherein in each of the bores one of the one or more temperature sensors is arranged. Said bores allow positioning the respective temperature sensor within the bulk of the enclosure, thereby reducing the amount of enclosure material between the temperature sensor and the source element. Hence, the bores preferably end in the vicinity to the source element. In summary, arranging the temperature sensor in a bore in the bulk of the enclosure helps improving the accuracy of the temperature measurement.

According to another embodiment, the source arrangement according to the present invention can be characterized in that the enclosure comprises cooling ducts for a flow of a liquid and/or gaseous coolant. By said cooling ducts, in particular by the flow of a liquid and/or gaseous coolant through the cooling ducts, an active cooling of the enclosure can be provided. Said cooling helps avoiding outgassing of the surrounding of the source element, in particular in the reaction chamber of the TLE system. Especially, such a cooling holds the enclosure at a fixed temperature, or at least below a critical temperature, at which adverse effects such as outgassing would occur. Further, in embodiments with two or more source elements provided by a single source arrangement, the cooling provided by the cooling ducts thermally isolates the individual source elements from each other.

Further, the source arrangement according to the present invention can be enhanced by that the cooling ducts are arranged within the enclosure at least in the region of the free space. As mentioned above, the evaporated and/or sublimated source material can be deposited onto the wall enclosing the free space and successively be reemitted, forming parts of the distribution of the evaporated and/or sublimated source material adjacent to the wing parts. By actively cooling the enclosure in the region of the free space, said reemitting can be reduced. Further, for embodiments of the source arrangement in which the enclosure provides the mirror surface, actively cooling the enclosure in the region of the free space can counter the energy deposition of the non-reflected laser beam into the material of the enclosure.

According to a second aspect of the invention, the object is satisfied by a TLE system comprising a laser source for providing a laser beam, a reaction chamber for containing a reaction atmosphere, a source arrangement for providing a source element comprising or consisting of a source material to be evaporated and/or sublimated by the laser beam within the reaction chamber, and a substrate arrangement for providing a substrate to be coated within the reaction chamber with the evaporated and/or sublimated source material, wherein the source arrangement is constructed according to one of the preceding claims and the laser beam and the source arrangement are provided and arranged such that a direct line-of-sight between the laser beam and the source element is completely blocked by the source arrangement, and by that the laser beam is reflected one or more times on the mirror surface of the source arrangement before impinging on the source element.

In the TLE system according to the second aspect of the present invention, a laser beam provided by a laser source is used for evaporating and/or sublimating a source material for a deposition of the evaporated and/or sublimated source material onto a substrate provided by a substrate arrangement. In most of the cases, the laser beam is coupled into the reaction chamber via coupling means. Said coupling means can be for instance simple entrance windows in a chamber wall of the reaction chamber. In addition, within the reaction chamber guidance elements can be arranged such as laser mirrors, focusing elements, and/or apertures, for guiding and/or shaping the laser beam before.

The source is arranged within the reaction chamber, which is sealable against ambient atmosphere and fillable with a reaction atmosphere. Said reaction atmosphere can be vacuum, in particular as low as 10-12 hPa or even lower, or comprise reaction gases at pressures suitable for the material to be deposited, for instance a reaction gas providing oxygen for a deposition of an oxide of an evaporated source material.

The TLE system according to the second aspect of the present invention comprises a source arrangement according to the first aspect of the present invention. By that, the TLE system according to the second aspect of the present invention provides all features and advantages described above with respect to a source arrangement according to the first aspect of the present invention.

In particular, in the TLE system according to the present invention, the source arrangement and the laser beam are positioned and aligned in such a way, that a direct line-of-sight of the laser beam to the source element provided within the support of the source arrangement is blocked. Hence for the evaporation and/or sublimation of the source material, the laser beam is reflected at least one time on the mirror surface provided by the source arrangement according to the first aspect of the present invention. Whereas this allows evaporating and/or sublimating the source material with a flux distribution well centered to the central axis of the free space in the support of the source arrangement, it simultaneously allows arranging the laser source, or at least the last element of the guidance system of the laser system such as the entrance window, a mirror and/or a focusing element, outside and away from this well-defined flux of evaporated and/or sublimated source material. Undesired or even harmful coating of elements present within the reaction camber, especially such as the aforementioned inner surface of entrance windows or laser mirrors and/or focusing elements, can thereby be avoided.

According to an embodiment of the TLE system according to the present invention, the source arrangement comprises two or more supports, wherein each of the supports carries a single source element, and/or TLE system comprises two or more source arrangements. In other words, in the reaction chamber of the TLE system two or more source elements are present. Said source elements can comprise the same source material or different source materials. Thereby, with accordingly provided laser beams the TLE system can provide an alternating deposition or co-deposition with source material evaporated and/or sublimated from the two or more source elements. In particular, with source elements providing the same source material, a deposition rate can be increased and/or spatial variations of the flux of evaporated and/or sublimated source material can be provided. Alternatively, or additionally, with source elements providing different source materials, a combined deposition of said different evaporated and/or sublimated source materials, in particular with constant or variable composition, can be provided.

Further, the TLE system according to the present invention can comprise that the support and the substrate arrangement are positioned such in the reaction chamber that a virtual extension of the central axis beyond the upper end of the free space hits the substrate, in particular hits a center of the substrate and/or orthogonally hits the substrate. In other words, the substrate provided by the substrate arrangement can be positioned and aligned to the center part of the distribution of evaporated and/or sublimated source material. A centered deposition of source material onto the substrate and a coating of the substrate can thereby be optimized. Alternatively, the substrate provided by the substrate arrangement can be positioned and aligned to the center part of the distribution of evaporated and/or sublimated source material such that the virtual extension of the central axis hits the substrate, preferably orthogonally, with a distance to the center of the substrate. In this embodiment, the substrate arrangement preferably comprises an actuator for moving, in particular rotating, the substrate with respect to the distribution of evaporated and/or sublimated source material. Hence a larger area of the substrate can be coated with the evaporated and/or sublimated source material. In particular, also for instance ring-shaped coatings can be provided, wherein the radius of the ring depends on the distance between the center of the distribution of evaporated and/or sublimated source material and the rotational axis of the substrate.

In addition, the TLE system can be characterized in that the support of the source arrangement is at least partly provided by a chamber wall of the reaction chamber. Hence, the support of the source arrangement is at least partly integrated into the chamber wall. Additional means for arranging and/or aligning the support within the reaction chamber can be avoided. The overall setup of the TLE system according to the present invention can thereby be simplified.

According to a further enhancement of the TLE system according to the present invention, the support comprises an enclosure and one or more temperature sensors are arranged at and/or within the enclosure, and/or the enclosure comprises cooling ducts, and wherein the one or more temperature sensors and/or the cooling ducts are accessible from outside of the reaction chamber. As mentioned above, the support of the source arrangement is directly integrated into the chamber wall of the reaction chamber. This also allows in the present enhanced embodiment a direct access to the temperature sensor and/or the cooling ducts. Additional feedthroughs in the chamber wall, which are not only complicated and expensive but also increase required maintenance, can be avoided.

Further, the TLE system according to the present invention can be characterized in that the TLE system comprises two or more laser sources and/or the laser source provides one or more laser beams, and wherein the two or more laser beams are guided within the reaction chamber for evaporating and/or sublimating the source material of the same source element. The use of more than one laser beams for evaporating and/or sublimating the same source material offer a more uniform and thereby efficient heating of the source material, as it is more symmetric. Again, the two or more laser beams are reflected by the mirror surface within the source arrangement one or more times, thereby allowing positioning and aligning the two or more laser beams outside of the central part of the resulting flux distribution of the evaporated and/or sublimated source material.

In an embodiment of the TLE system according to the present invention, the laser beam is provided with a wavelength between 100 nm and 10 μm, preferably around 1 μm. Laser beams with wavelength between 100 nm and 10 μm, preferably around 1 μm, are most suitable for evaporating and/or sublimating source materials, especially the source materials mentioned in the next paragraph. In addition, laser beams with said wavelengths are available with very high wallplug efficiencies and low cost per kW.

Further, the TLE system according to the present invention can comprise that the source material of the source element comprises, preferably consists of, at least one of the following elements:
arsenic
antimony
tellurium
sulfur
selenium.

This listing contains the preferred source materials, however also other source materials are possible. In particular, all solid and liquid elements and compounds can be used as source materials in the TLE system according to the present invention.

According to a third embodiment of the invention, the object is solved by a method for using a TLE system, the TLE system comprising a laser source for providing a laser beam, a reaction chamber for containing a reaction atmosphere, a source arrangement for providing a source element comprising or consisting of a source material to be evaporated and/or sublimated by the laser beam within the reaction chamber, and a substrate arrangement for providing a substrate to be coated within the reaction chamber with the evaporated and/or sublimated source material, the method comprising the following steps:
a) Providing the laser beam with a direction such that a direct line-of-sight between the laser beam and the source element is completely blocked by the source arrangement,
b) Reflecting the laser beam one or more times within the source arrangement before impinging on the source element,
c) Evaporating and/or sublimating the source material by the reflected laser beam, and
d) Depositing the source material evaporated and/or sublimated in step c) onto the substrate.

The method according to the present invention can be carried out with a TLE system comprising the basic elements of a TLE system such as a laser source for providing a laser beam, a reaction chamber, a source element, and a substrate. Further, the TLE system comprises the required arrangement means for the source element and the substrate.

Essential for the method according to the present invention are the relative arrangement and alignment of the laser beam, the source element and the substrate, respectively. In particular, the source element and the substrate are arranged preferably with a direct line-of-sight to each other to provide or even optimize the deposition of the evaporated and/or sublimated source material onto the substrate in step d). However, the laser beam is provided in step a) without such a line-of-sight to the source element. This provides the feature and advantage that source material evaporated and/or sublimated with a moving direction towards the laser source or at least towards the last optical element of the laser system such as a mirror or an entrance window, are somewhere blocked and deposited elsewhere. Unwanted and harmful coating of the optical elements can thereby be avoided or at least reduced.

In order to nevertheless allow an evaporation and/or sublimation of the source material by the laser beam, the laser beam is reflected within the source arrangement in step b) of the method according to the present invention. Hence, in the following step c) the laser beam impinges onto the source element and evaporates and/or sublimates the respective source material.

In particular, the method according to the present invention can be characterized in that the TLE system is constructed according to the second aspect of the present invention. The TLE system according to the second aspect of the present invention comprises a source arrangement according to the first aspect of the present invention. Hence, in this embodiment, the method according to the third aspect of the present invention provides all features and advantages described above with respect to a source arrangement according to the first aspect of the present invention and to a TLE system according to the second aspect of the present invention.

The invention will be explained in detail in the following by means of embodiments and with reference to the drawings in which are shown:

FIG. 1 Schematic view ofs an elongated crucible and of a resulting distribution of the flux of source material across the substrate plane,

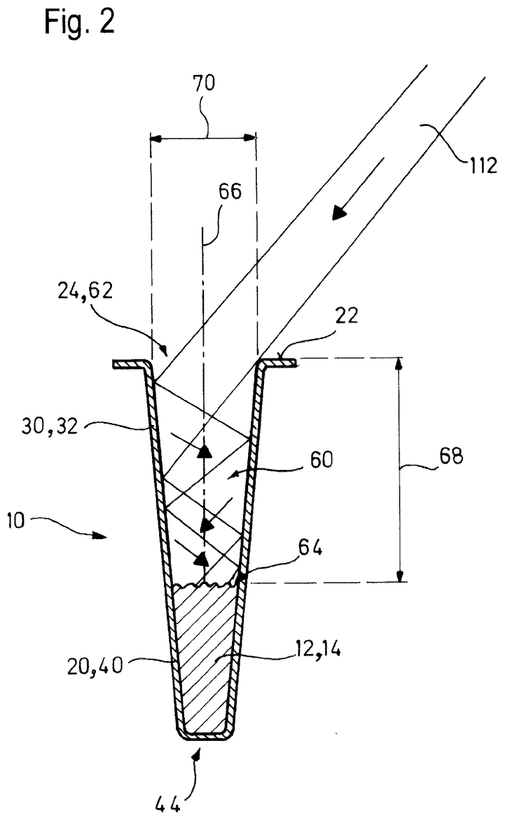

FIG. 2A schematic cross section of a first embodiment of a source arrangement according to the present invention,

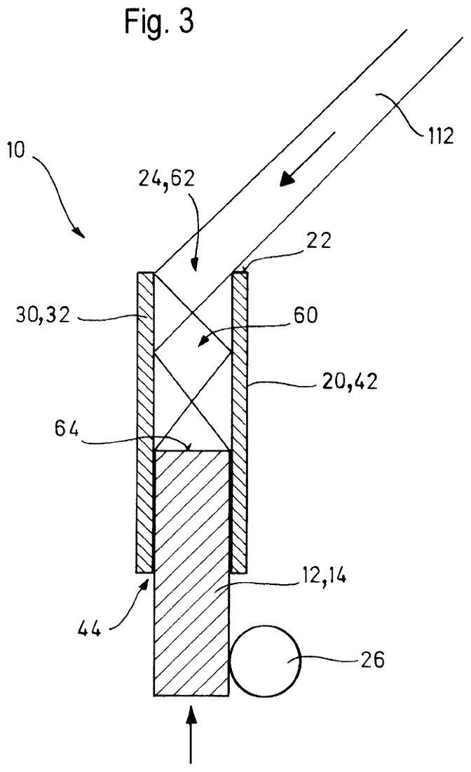

FIG. 3A schematic cross section of a second embodiment of a source arrangement according to the present invention,

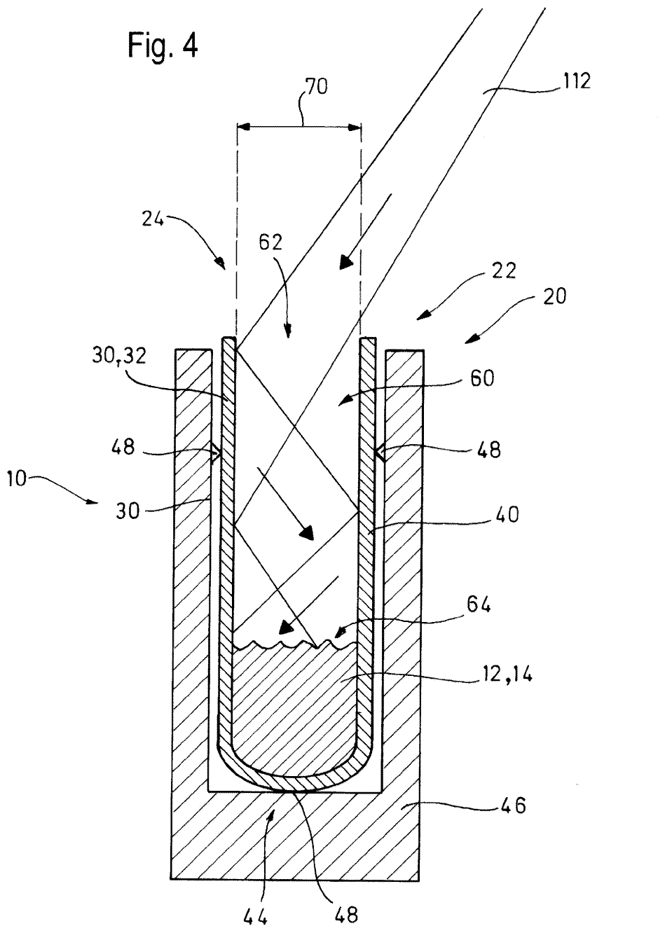

FIG. 4A schematic cross section of a third embodiment of a source arrangement according to the present invention,

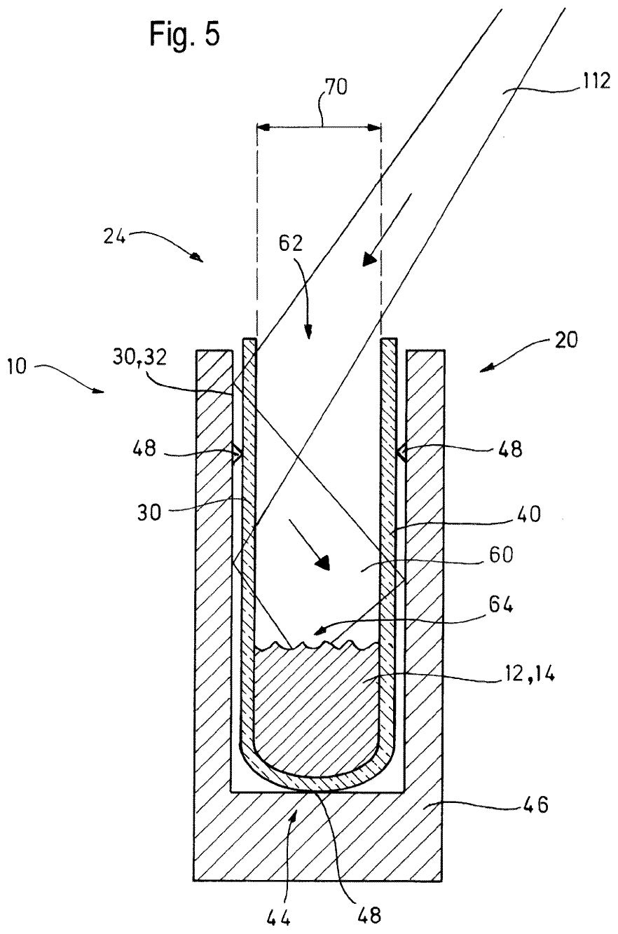

FIG. 5A schematic cross section of a fourth embodiment of a source arrangement according to the present invention,

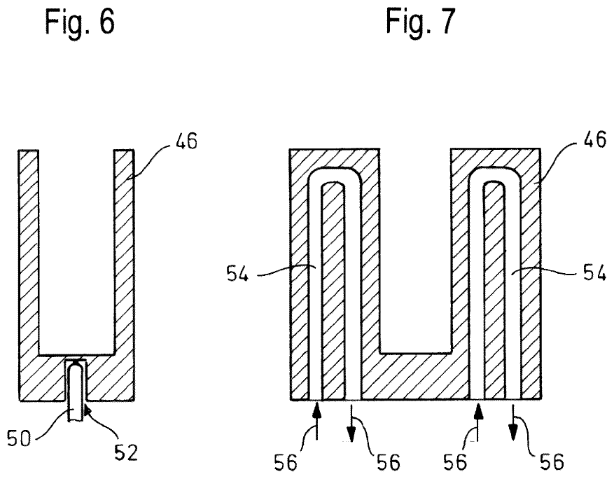

FIG. 6A schematic cross section of a first embodiment of an enclosure of a source arrangement according to the present invention,

FIG. 7A schematic cross section of a second embodiment of an enclosure of a source arrangement according to the present invention,

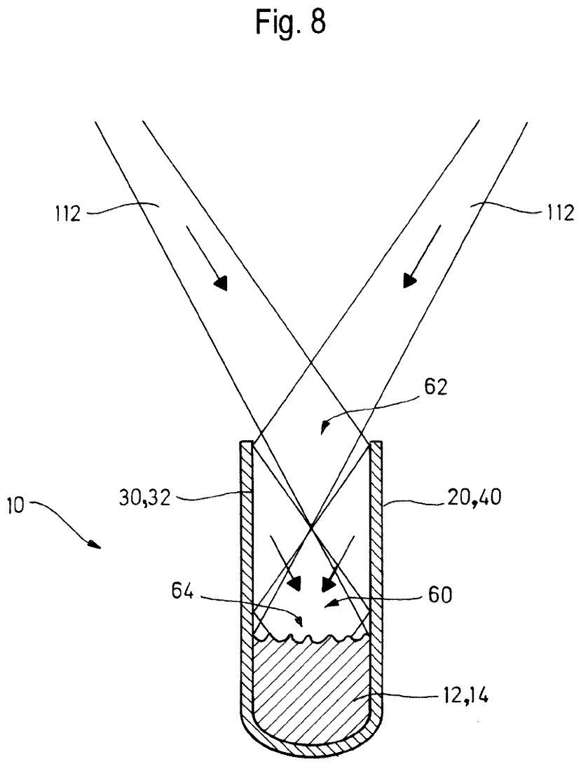

FIG. 8 Evaporating source material with a source arrangement according to the present invention and two laser beams, and

FIG. 9A schematic cross section of a TLE system according to the present invention.

FIGS. 2 to 5 show various embodiments of source arrangements 10 according to the present invention. To avoid repetition, common elements of all embodiments will be described in general terms below, while differences in the respective embodiments will be discussed in detail.

All source arrangements 10 described in the following are intended for a usage in a TLE system 100 as depicted for instance in FIG. 9. The source arrangements are capable of providing a source element 12 comprising or consisting of source material 14. Said source material 14 can be a single element such as for instance arsenic, antimony, tellurium, sulfur or selenium. Alternatively, the source material 14 also can be a chemical compound. A laser beam 112 with suitable wavelength, often between 100 nm and 10 μm, preferably around 1 μm, is used for evaporation and/or sublimation of the source material 14.

Essential for the present invention, the laser beam 112 impinges not directly onto a surface of the source element 12 as a direct line-of-sight of the laser beam 112 to the source element 12 is blocked. This is partly due to the design of the support 20 of the source arrangement 10. The support 20 encloses a free space 60 free of any structural element of the support 20, the free space 60 starting at an opening 24 in a surface portion 22 of the support and extending inwards into the support 10. The free space 60 is elongated along a central axis 66 of the free space 60 and thereby has a columnar shape. In other words, the free space 60 starts at an upper end 62 defined by the opening 24, extends along its central axis 66 and is limited by its lower end 64 defined by the source element 12. Designing the opening 24 larger or at least equal in size to the upper end 62 of the free space 60 prevents shadowing effects, however is not required.

According to the present invention, a wall structure 30 of the support 20 surrounds the free space 60 between the upper end 62 and the lower end 64. In particular, said wall structure 30 comprises a mirror surface 32 reflective to the laser beam 112. Hence, the laser beam 112 impinging on said mirror surface 32 will be reflected and finally guided towards the source element 12, thereby causing the source material to be evaporated and/or sublimated. This allows to arrange and align the lase beam 112 way out of the central part 16, and preferably also out of the wing part 18, of the distribution of the evaporated and/or sublimated source material 14 as depicted in FIG. 1. Thereby all advantages of such a distribution of evaporated and/or sublimated source material 14 comprising a well-defined high intensity central part 16 with very low radial dependence can be provided, with simultaneously avoiding an unwanted and possibly harmful coating of elements of the laser system such as for instance mirrors or entrance windows 126 (see FIG. 9).

Said mirror surface 32 preferably completely encompasses the free space 60 along the central axis 66. First of all, this simplifies the provision of multiple reflections of the laser beam 112 on the mirror surface 32. Further, also a placement and alignment of the source arrangement 10 within a reaction chamber 120 (see FIG. 9) can be made easier and less prone to error. Said provision of multiple reflections can be supported by designing the free space 60 with an extent 68 along the central axis 66 equal or larger than a diameter 70 of its upper end 62, as exemplarily depicted in FIG. 2. Providing the mirror surface 32 with a wavy surface structure, preferably along the direction normal to the laser beam 112 and tangential to the cross-section of the mirror surface normal to the approximate symmetry axis, in most of the embodiments the central axis 66, of the free space 60, helps avoiding unwanted focusing effects by diffusing the reflected laser beam 112, especially but not limited to free spaces 60 which are rotationally symmetric about their respective central axis 66.

FIG. 2 depicts an embodiment with a conical crucible 40 forming the support 20. The crucible 40 comprises a closed bottom end 44 and thereby provides a secure arrangement space for the source element 12, even for liquid source materials 14. Further, in the depicted embodiment the crucible 40 itself provides the wall structure 30 and in particular the mirror surface 32.

In contrast to the embodiment depicted in FIG. 2, the support 20 of the source arrangement 10 shown in FIG. 3 comprises a retainer 42 which in turn comprises an open bottom end 44. Again, the retainer 42 as part of the wall structure 30 provides the mirror surface 32 for reflecting the laser beam 112. The retainer 42 with its open bottom end 44 allows guiding a columnar and in particular self-supporting source element 12 into the retainer 42. An actuator 26 can be used for moving the source element 12 up towards the upper end 62 of the free space 60, preferably at a pace compensating the amount of source material 14 evaporated and/or sublimated by the impinging laser beam 112.

Preferably, crucibles 40 and retainers 42 providing the mirror surface 32 are made of aluminum or tantalum or molybdenum or stainless steel.

Another possible embodiment of the source arrangement 10 according to the present invention is depicted in FIG. 4. In addition to the crucible 40 depicted in FIG. 2 and the retainer 42 depicted in FIG. 3, the support 20 can further comprise an enclosure 46 surrounding said crucible 40 (as shown in FIG. 4) or retainer 42 (not depicted). Preferably, the enclosure 46 is made of Aluminum. Especially with crucibles 40, such an enclosure 46 preferably completely encompass the free space 60. Thereby, even if the crucible 40 fails, the source material 24 is contained within the enclosure 46 and hence within the support 20 of the source arrangement 10.

The crucible 40 is arranged within the enclosure 46 and touches the enclosure at three contact points 48. This on the one hand secures the positioning of the crucible 40 within the enclosure 46 and on the other hand minimizes thermal contact between these elements of the source arrangement 10.

As an alternative to the conical crucible 40 shown in FIG. 2, the crucible 40 depicted in FIG. 4 comprises a cylindrical shape. Again, the surface of the crucible 40 facing the free space 60 provides the mirror surface 32.

Also FIG. 5 depicts an embodiment of the source arrangement 10 according to the present invention with a cylindrical crucible 40 arranged in an enclosure 46. Again, the crucible 40 touches the enclosure 46 at three contact points 48, wherein the enclosure 46 completely encloses the crucible 40.

In contrast to the embodiments of the source arrangement 10 shown in the FIGS. 2 to 4, in which the depicted crucibles 40 or retainers 42, respectively, provide the mirror surface 32, in FIG. 5 the material of the used crucible 40 is at least partly transparent for the laser beam 112. For instance, the crucible 40 is made of quartz or sapphire or borosilicate glass. Further, the enclosure 46, in particular at least the surface of the enclosure 46 facing the crucible 40, forms the mirror surface 32 as part of the wall structure 30.

In summary, in this embodiment of the source arrangement 10 according to the present invention, the laser beam 112 enters the free space 60 through its upper end 62, is transmitted through the transparent wall of the crucible 40 and successively reflected on the mirror surface 32 provided by the enclosure 46, at least once, preferably two or more times. In the end, the reflected laser beam 112 impinges at the lower end 64 of the free space 60 onto the surface of the source element 12 and source material 14 is evaporated and/or sublimated. As the free space 60 is elongated, the resulting flux distribution of the evaporated and/or sublimated source material 14 comprises a central part 16 (see FIG. 1) with a width defined by the diameter 70 of the free space 60

FIGS. 6 and 7 show possibilities for enhanced further developments of the enclosure 46 of a source arrangement 10 according to the present invention. Both enhancements can be implemented either independently or combined.

In FIG. 6, the enclosure 46 comprises a bore 52 starting at an outer surface of the enclosure 46 and ending in the vicinity to the inner volume of the enclosure 46, in which for instance a crucible 40 can be arranged (see FIG. 4, 5). A temperature sensor 50, for instance a thermocouple or a pyrometer, is inserted into the bore 52 for an indirect measurement of the temperature of a source element 12 arranged within the enclosure 46 (see again FIG. 4, 5). The measured temperature information can for instance be used for controlling, preferably in a closed loop control, the rate and/or flux of evaporated and/or sublimated source material 14.

Alternatively, or additionally, as depicted in FIG. 7, the enclosure 46 can also comprise cooling ducts 54 for a flow of coolant 56. Hence, the bulk of the enclosure 46 can be cooled at a certain temperature, or at least the temperature of the enclosure 46 can be kept below a certain temperature limit. As depicted, the cooling ducts 54 are arranged within the enclosure 46 especially in the region, in which after inserting a crucible 40 or a retainer 42, respectively, comprising a source element 14, will be located (see FIG. 4, 5). Constant conditions for the evaporation and/or sublimation of the source material 14 provided by the source arrangement 10 according to the present invention can thereby be ensured more easily.

In FIG. 8, a possible enhancement of the evaporation and/or sublimation process rendered possible by the source arrangement 10 according to the present invention is shown. In particular, not only a single laser beam 112, but two laser beams 112 are used, both of them arranged such that the respective laser beam 112 is at least once reflected on the mirror surface 32 before impinging on the source element 12. The remaining elements depicted in FIG. 8 resemble the embodiment already shown and described with respect to FIG. 4. The use of more than one laser beams 112 for evaporating and/or sublimating the same source material 14 offer a more uniform and thereby efficient heating of the source material 14, as it is more symmetric.

FIG. 9 shows a schematic and drastically simplified embodiment of a TLE system 100 according to the present invention. A source arrangement 10 according to the present invention is arranged within a reaction chamber 120. The volume enclosed by a chamber wall 122 of the reaction chamber 120 is filled with a reaction atmosphere 124, for instance vacuum or suitable reaction gases chosen according to the evaporation and/or sublimation process to be established.

A laser source 110 provides a laser beam 112, which is coupled into the reaction chamber 120 via an entrance window 126. The direction of the laser beam 112 is aligned such that a direct line-of-sight to the source element 12 provided by the source arrangement 10 is blocked. However, as described with respect to FIGS. 2 to 5, the laser beam 112 is reflected on the mirror surface 32 provided by the wall structure 30 of the support 20 of the source arrangement 10 and hence nevertheless impinges onto the source element 12.

The thereby evaporated and/or sublimated source material 14 comprises a flux distribution aligned to the central axis 66 of the free space 60. As the laser beam 112, and hence for instance the entrance window 126, are located at a distance to this directed emission of evaporated and/or sublimated source material 14, an unwanted and harmful deposition of source material 14 can be avoided.

Additionally, the substrate 132 provided by a substrate arrangement 130 is preferably arranged such in the reaction chamber 120 that a virtual extension 80 of the central axis 66 orthogonally hits a center of the substrate 132. By this, a centered deposition of source material 14 onto the substrate 132 and a coating of the substrate 132 is optimized. Alternatively, one may also arrange the substrate 132 such that the virtual extension 80 of the central axis 66 hits the substrate 132 with an optimized lateral offset to the center of the substrate 132. In particular combined with a movement of the substrate 132, preferably a rotation of the substrate 132 around a substrate rotation axis 134 as indicated in FIG. 9, provided by an actuator of the substrate arrangement 130, a ring-shaped deposition of source material 14 onto the substrate 132 can be provided. In all embodiments, also an angled alignment of the substrate 132 with respect to the virtual extension 80 of the central axis 66 is possible. Further, as depicted in FIG. 9, the support 20 of the source arrangement 10, in particular the enclosure 46, can be provided by the chamber wall 122 of the reaction chamber 120. An arrangement and in particular an alignment of the source arrangement 10 within the reaction chamber 120 can thereby be provided more easily.

In addition, such an integration of the enclosure 46 into the chamber wall allows direct access to both cooling ducts 54 and bores 52 and the therein positioned temperature sensors, respectively, arranged within the enclosure 46. Additional feedthroughs in the chamber wall 122, which are not only complicated and expensive but also increase required maintenance, can be avoided.

### List of References

10 Source arrangement
12 Source element
14 Source material
16 Distribution—central part
18 Distribution—wing part
20 Support
22 Surface portion
24 Opening
26 Actuator
30 Wall structure
32 Mirror surface
40 Crucible
42 Retainer
44 Bottom end
46 Enclosure
48 Contact point
50 Temperature senor
52 Bore
54 Cooling duct
56 Coolant
60 Free space
62 Upper end
64 Lower end
66 Central axis
68 Extent
70 Diameter
80 Extension
100 TLE system
110 Laser source
112 Laser beam
120 Reaction chamber
122 Chamber wall
124 Reaction atmosphere
126 Entrance window
130 Substrate arrangement
132 Substrate
134 Substrate rotation axis

1-35. (canceled)

36. Source arrangement for a TLE system for providing a source element comprising or consisting of a source material to be evaporated and/or sublimated by a laser beam,
comprising a support carrying said source element,
wherein the support encloses a free space free of any structural elements of the support, whereby the free space is elongated along a central axis of the free space and thereby has a columnar shape,
wherein an opening disposed in a surface portion of the support provides access from outside of the support to the free space, the opening defining an upper end of the free space, and the source element disposed within the support spaced from the opening along the central axis of the free space defining a lower end of the free space,
and wherein a wall structure of the support surrounding the free space between the upper end and the lower end comprises a mirror surface reflective to the laser beam.

37. Source arrangement according to claim 36,
wherein the mirror surface completely encompasses the free space along the central axis.

38. Source arrangement according to claim 36,
wherein the mirror surface at least partly comprises a wavy surface structure for diffusing the reflected laser beam.

39. Source arrangement according to claim 36,
wherein the cross section of the opening completely contains the cross section of the upper end of the free space.

40. Source arrangement according to claim 39,
wherein the cross section of the opening is identical to the cross section of the upper end of the free space.

41. Source arrangement according to claim 36,
wherein an extent of the free space along the central axis is equal to or larger than a diameter of its upper end.

42. Source arrangement according to claim 36,
wherein the free space is rotationally symmetric to the central axis.

43. Source arrangement according to claim 42,
wherein the free space is cylindrical.

44. Source arrangement according to claim 42,
wherein the free space is conical.

45. Source arrangement according to claim 36,
wherein the support comprises a crucible of tubular shape with a closed bottom end, whereby the source element is arranged at the bottom end and the crucible encompasses the free space and is thus partially at least part of the wall structure of the support.

46. Source arrangement according to claim 36,
wherein the source element is self-supporting and the support comprises a retainer of tubular shape with an open bottom end, whereby the source element is inserted through the bottom end into the retainer, and the retainer encompasses the free space and is thus at least partially part of the wall structure of the support.

47. Source arrangement according to claim 46,
wherein the support comprises an actuator for moving the source element within the retainer.

48. Source arrangement according to claim 45,
wherein the support comprises an enclosure surrounding one or more crucibles and/or retainers along the central axis at least in the region of the free space of the respective crucible or retainer and is thus at least partially part of the wall structure of the support.

49. Source arrangement according to claim 48,
wherein the enclosure completely encloses the one or more crucibles and/or retainers and the respective source elements except for an opening forming the upper end of the free space.

50. Source arrangement according to claim 45,
wherein a surface of the crucible or the retainer facing the free space is the mirror surface of the wall structure of the support.

51. Source arrangement according to claim 50,
wherein at least the portion of the crucible or the retainer forming the mirror surface is made of aluminum or tantalum or molybdenum or stainless steel.

52. Source arrangement according to claim 49,
wherein a material of the crucible or the retainer is at least partly transparent for the laser beam and a surface of the enclosure facing the free space is the mirror surface of the wall structure of the support.

53. Source arrangement according to claim 52,
wherein the crucible or the retainer is at least partly made of quartz or sapphire or borosilicate glass.

54. Source arrangement according to claim 48,
wherein the enclosure is least partly made of Aluminum.

55. Source arrangement according to claim 48,
wherein the crucible or the retainer and the enclosure touch at three contact points.

56. Source arrangement according to claim 48,
wherein the support comprises one or more temperature sensors arranged at and/or within the enclosure for measuring the temperature of the source element.

57. Source arrangement according to claim 56,
wherein the one or more temperature sensor is a thermocouple or a pyrometer.

58. Source arrangement according to claim 56,
wherein the enclosure comprises one or more bores, wherein in each of the bores one of the one or more temperature sensors is arranged.

59. Source arrangement according to claim 48,
wherein the enclosure comprises cooling ducts for a flow of a liquid and/or gaseous coolant.

60. Source arrangement according to claim 59,
wherein cooling ducts are arranged within the enclosure at least in the region of the free space.

61. TLE system comprising a laser source for providing a laser beam, a reaction chamber for containing a reaction atmosphere, a source arrangement for providing a source element comprising or consisting of a source material to be evaporated and/or sublimated by the laser beam within the reaction chamber, and a substrate arrangement for providing a substrate to be coated within the reaction chamber with the evaporated and/or sublimated source material,
wherein the source arrangement is constructed according to one of the preceding claims and the laser beam and the source arrangement are provided and arranged such that a direct line-of-sight between the laser beam and the source element is completely blocked by the source arrangement, and by that the laser beam is reflected one or more times on the mirror surface of the source arrangement before impinging on the source element.

62. TLE system according to claim 61,
wherein the source arrangement comprises two or more supports, wherein each of the supports carries a source element, and/or TLE system comprises two or more source arrangements.

63. TLE system according to claim 61,
wherein the support and the substrate arrangement are positioned such in the reaction chamber that a virtual extension of the central axis beyond the upper end of the free space hits the substrate.

64. TLE system according to claim 61,
wherein the support of the source arrangement is at least partly provided by a chamber wall of the reaction chamber.

65. TLE system according to claim 64,
wherein the support comprises an enclosure and wherein one or more temperature sensors are arranged at and/or within the enclosure, and/or the enclosure comprises cooling ducts, and wherein the one or more temperature sensors and/or the cooling ducts are accessible from outside of the reaction chamber.

66. TLE system according to claim 61,
wherein the TLE system comprises two or more laser sources and/or the laser source provides one or more laser beams, and wherein the two or more laser beams are guided within the reaction chamber for evaporating and/or sublimating the source material of the same source element.

67. TLE system according to claim 61,
wherein the laser beam is provided with a wavelength between 100 nm and 10 μm.

68. TLE system according to claim 61, wherein the source material of the source element comprises at least one of the following elements:
arsenic
antimony
tellurium
sulfur
selenium.

69. Method for using a TLE system, the TLE system comprising a laser source for providing a laser beam, a reaction chamber for containing a reaction atmosphere, a source arrangement for providing a source element comprising or consisting of a source material to be evaporated and/or sublimated by the laser beam within the reaction chamber, and a substrate arrangement for providing a substrate to be coated within the reaction chamber with the evaporated and/or sublimated source material, the method comprising the following steps:
a) Providing the laser beam with a direction such that a direct line-of-sight between the laser beam and the source element is completely blocked by the source arrangement,
b) Reflecting the laser beam one or more times within the source arrangement before impinging on the source element,
c) Evaporating and/or sublimating the source material by the reflected laser beam, and
d) Depositing the source material evaporated and/or sublimated in step c) onto the substrate.

70. Method according to claim 69,
wherein the TLE system comprises a laser source for providing a laser beam, a reaction chamber for containing a reaction atmosphere, a source arrangement for providing a source element comprising or consisting of a source material to be evaporated and/or sublimated by the laser beam within the reaction chamber, and a substrate arrangement for providing a substrate to be coated within the reaction chamber with the evaporated and/or sublimated source material,
wherein the source arrangement is constructed according to one of the preceding claims and the laser beam and the source arrangement are provided and arranged such that a direct line-of-sight between the laser beam and the source element is completely blocked by the source arrangement, and by that the laser beam is reflected one or more times on the mirror surface of the source arrangement before impinging on the source element.
